(19) United States
(12) Patent Application Publication
(10) Pub. No.: US 2025/0166701 A1
(43) Pub. Date: May 22, 2025

(54) SEMICONDUCTOR DEVICE AND OPERATING METHOD OF THE SAME

(71) Applicant: SK hynix Inc., Icheon-si (KR)

(72) Inventor: Take Kyun WOO, Icheon-si (KR)

(21) Appl. No.: 18/623,336

(22) Filed: Apr. 1, 2024

(30) Foreign Application Priority Data
Nov. 16, 2023 (KR) 10-2023-0159089

(51) Int. Cl. G11C 13/00

(52) U.S. Cl. CPC G11C 13/0069; G11C 2013/0073

(57) ABSTRACT

A semiconductor device may include a memory cell connected to a first line and a second line, at least one of first transistors each configured to provide a first input voltage of a first node to the first line, and at least one of second transistors each configured to provide a second input voltage of a second node to the second line. Polarities of the first and second input voltages provided to the first and second nodes may be determined based on data to be written in the memory cell. At least one of a voltage of each of control terminals of the first and second transistors and a back bias voltage of each of the first and second transistors is adjusted in response to a change in the polarity of each of the first and second input voltages.

### CROSS-REFERENCE TO RELATED APPLICATION

This application claims priority under 35 U.S.C. § 119 to Korean Patent Application No. 10-2023-0159089 filed on Nov. 16, 2023, which is incorporated herein by reference in its entirety.

### BACKGROUND

### 1. Technical Field

Embodiments relate to a semiconductor device that provides a forward current or a backward current to a memory cell based on the level of data to be written and an operating method of the same.

### 2. Related Art

Recently, as an electronic device is reduced in size, has low power consumption and high performance, and is diversified, a semiconductor device capable of storing information is required for various electronic devices, such as computers and portable communication devices. Accordingly, research of a semiconductor device capable of storing data by using a characteristic in which the state of a memory cell switches between different resistance states depending on a voltage or a current that is applied to the memory cell is carried out. Such a semiconductor device includes resistive random access memory (RRAM), phase-change random access memory (PRAM), ferroelectric random access memory (FRAM), magnetic random access memory (MRAM), and an E-fuse.

Particularly, a semiconductor device using a switching characteristic in which the state of a memory cell is changed between different resistance states depending on a direction in which a current is applied to the memory cell is actively researched.

### SUMMARY

In an embodiment, a semiconductor device may include a memory cell connected to a first line and a second line, at least one of first transistors each configured to provide a first input voltage of a first node to the first line, and at least one of second transistors each configured to provide a second input voltage of a second node to the second line. The first and second nodes may be provided with the first and second input voltages having different polarities. The polarities of the first and second input voltages that are provided to the first and second nodes may be determined based on data to be written in the memory cell. At least one of a voltage of each of control terminals of the first and second transistors and a back bias voltage of each of the first and second transistors is adjusted in response to a change in the polarity of each of the first and second input voltages.

In an embodiment, an operating method of a semiconductor device may include providing a positive voltage to a first node, providing a negative voltage to a second node, connecting the first node to a bit line that is electrically connected to a first end of a memory cell by providing a second positive voltage to a gate of a column transistor, and connecting the second node to a word line that is electrically connected to a second end of the memory cell by providing a first positive voltage to a gate of a row transistor, the first positive voltage having a lower voltage level than the second positive voltage.

In an embodiment, an operating method of a semiconductor device may include providing a negative voltage to a first node, providing a positive voltage to a second node, connecting the first node to a bit line that is electrically connected to a first end of a memory cell by providing a first positive voltage to a gate of a column transistor, and connecting the second node to a word line that is electrically connected to a second end of the memory cell by providing a second positive voltage to a gate of a row transistor, the second positive voltage having a higher voltage level than the first positive voltage.

### BRIEF DESCRIPTION OF THE DRAWINGS

FIGS. 1 and 2 are diagrams for describing a structure and operation of a semiconductor device according to an embodiment of the present disclosure.

FIG. 3 is a diagram for conceptually describing a semiconductor device according to another embodiment of the present disclosure.

FIGS. 4 and 5 are diagrams for describing a structure and operation of a semiconductor device according to another embodiment of the present disclosure.

### DETAILED DESCRIPTION

Hereinafter, embodiments according to the technical spirit of the present disclosure are described with reference to the accompanying drawings. As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, only C, or both A and B, or both A and C, or both B and C, or all of A and B and C,” and so on.

Embodiments of the present disclosure may provide a semiconductor device that provides a forward current or a backward current to a memory cell based on the level of data to be written in the memory cell and an operating method of the same.

The reliability of a local switch that provides a memory cell with a forward current or a backward current can be improved.

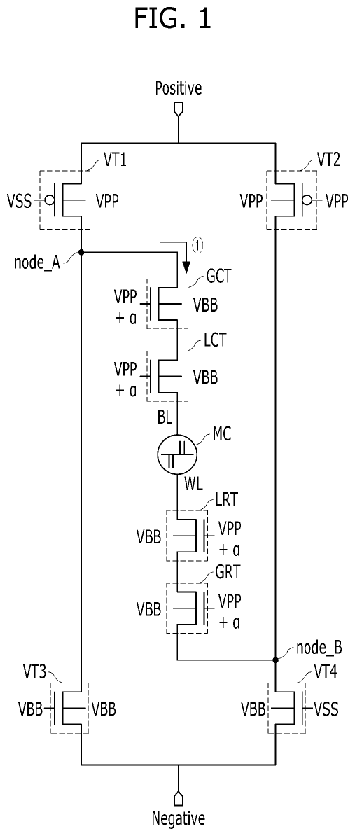

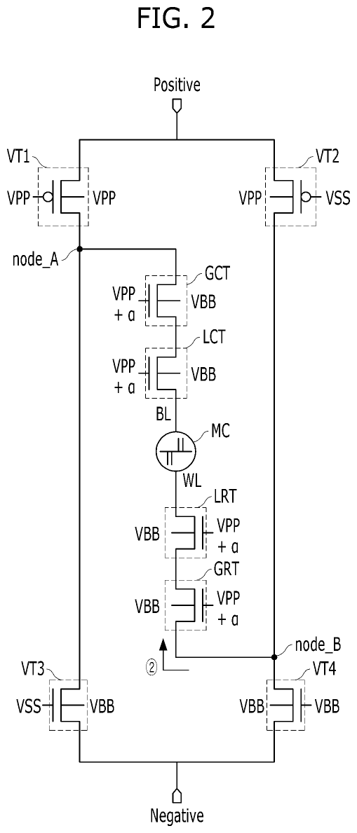

FIGS. 1 and 2 are diagrams for describing a structure and operation of a semiconductor device according to an embodiment of the present disclosure. FIGS. 1 and 2 are diagrams for describing a configuration and a write operation of the semiconductor device according to an embodiment of the present disclosure. FIG. 1 is a diagram for describing a write operation of providing a memory cell MC with a forward current \textcircled{1}. FIG. 2 is a diagram for describing a write operation of providing the memory cell MC with a backward current \textcircled{2}. In this case, the state of the memory cell MC may be switched between different resistance states depending on the direction of the current that is provided to the memory cell MC. That is, different data may be written into the memory cell MC depending on the direction of a current that is provided to the memory cell MC.

Referring to FIGS. 1 and 2, the semiconductor device according to an embodiment of the present disclosure may include a first voltage provision transistor VT1, a second voltage provision transistor VT2, a third voltage provision transistor VT3, a fourth voltage provision transistor VT4, a global first transistor (e.g., a global column transistor) GCT, a local first transistor (e.g., a local column transistor) LCT, a global second transistor (e.g., a global row transistor GRT), a local second transistor (e.g., a local row transistor) LRT, and the memory cell MC.

The first to fourth voltage provision transistors VT1, VT2, VT3, and VT4 may be constructed to selectively provide one of a first input voltage (e.g., a positive voltage) Positive and a second input voltage (e.g., a negative voltage) Negative to each of a first node node_A and a second node node_B. In this case, the first to fourth voltage provision transistors VT1, VT2, VT3, and VT4 may be controlled to provide the negative voltage Negative to the second node node_B when the positive voltage Positive is provided to the first node node_A. Furthermore, the first to fourth voltage provision transistors VT1, VT2, VT3, and VT4 may be controlled to provide the positive voltage Positive to the second node node_B when the negative voltage Negative is provided to the first node node_A.

For example, as illustrated in FIG. 1, when the forward current \textcircled{1} is provided to the memory cell MC, the first and fourth voltage provision transistors VT1 and VT4 may be turned on. The positive voltage Positive may be provided to the first node node_A by the first voltage provision transistor VT1 that has been turned on, and the negative voltage Negative may be provided to the second node node_B by the fourth voltage provision transistor VT4 that has been turned on. As illustrated in FIG. 2, when the backward current \textcircled{2} is provided to the memory cell MC, the second and third voltage provision transistors VT2 and VT3 may be turned on. The negative voltage Negative may be provided to the first node node_A by the third voltage provision transistor VT3 that has been turned on, and the positive voltage Positive may be provided to the second node node_B by the second voltage provision transistor VT2 that has been turned on.

The first voltage provision transistor VT1 may have a control terminal (e.g., a gate) provided with a ground voltage VSS or a first positive voltage VPP, a first terminal (e.g., a source) provided with the positive voltage Positive, and a second terminal (e.g., a drain) connected to the first node node_A. Furthermore, the first voltage provision transistor VT1 may be provided with the first positive voltage VPP as a back bias voltage. At this time, the first voltage provision transistor VT1 may be turned on when the ground voltage VSS is provided to the gate of the first voltage provision transistor VT1, and may be turned off when the first positive voltage VPP is provided to the gate of the first voltage provision transistor VT1. The positive voltage Positive may have a voltage level higher than or equal to the voltage level of the first positive voltage VPP.

The second voltage provision transistor VT2 may have a control terminal (e.g., a gate) provided with the first positive voltage VPP or the ground voltage VSS, a first terminal (e.g., a source) provided with the positive voltage Positive, and a second terminal (e.g., a drain) connected to the second node node_B. Furthermore, the second voltage provision transistor VT2 may be provided with the first positive voltage VPP as a back bias voltage. At this time, the second voltage provision transistor VT2 may be turned on when the ground voltage VSS is provided to the gate of the second voltage provision transistor VT2, and may be turned off when the first positive voltage VPP is provided to the gate of the second voltage provision transistor VT2.

The third voltage provision transistor VT3 may have a control terminal (e.g., a gate) provided with a negative voltage VBB or the ground voltage VSS, a first terminal (e.g., a drain) connected to the first node node_A, and a second terminal (e.g., a source) provided with the negative voltage Negative. Furthermore, the third voltage provision transistor VT3 may be provided with the negative voltage VBB as a back bias voltage. At this time, the third voltage provision transistor VT3 may be turned off when the negative voltage VBB is provided to the gate of the third voltage provision transistor VT3, and may be turned on when the ground voltage VSS is provided to the gate of the third voltage provision transistor VT3. For example, the negative voltage VBB may have substantially the same voltage level as the negative voltage Negative.

The fourth voltage provision transistor VT4 may have a control terminal (e.g., a gate) provided with the ground voltage VSS or the negative voltage VBB, a first terminal (e.g., a drain) connected to the second node node_B, and a second terminal (e.g., a source) provided with the negative voltage Negative. Furthermore, the fourth voltage provision transistor VT4 may be provided with the negative voltage VBB as a back bias voltage. At this time, the fourth voltage provision transistor VT4 may be turned off when the negative voltage VBB is provided to the gate of the fourth voltage provision transistor VT4, and may be turned on when the ground voltage VSS is provided to the gate of the fourth voltage provision transistor VT4.

The global column transistor GCT and the local column transistor LCT may be constructed to electrically connect or separate the first node node_A and a first line (e.g., a bit line) BL. When the global column transistor GCT and the local column transistor LCT are turned on, the global column transistor GCT and the local column transistor LCT may electrically connect the first node node_A and the bit line BL. In this case, the global column transistor GCT and the local column transistor LCT that have been turned on may provide a voltage that is provided to the first node node_A, that is, one of the positive voltage Positive and the negative voltage Negative, to the bit line BL.

For example, referring to FIG. 1, when the first voltage provision transistor VT1 is turned on and the positive voltage Positive is provided to the first node node_A, the positive voltage Positive may be transferred to the bit line BL by the global column transistor GCT and the local column transistor LCT that have been turned on. Referring to FIG. 2, when the third voltage provision transistor VT3 is turned on and the negative voltage Negative is provided to the first node node_A, the negative voltage Negative may be transferred to the bit line BL by the global column transistor GCT and the local column transistor LCT that have been turned on.

At this time, as illustrated in FIGS. 1 and 2, in the state in which the first node node_A and the local column transistor LCT have been connected to a first terminal (e.g., a drain) and a second terminal (e.g., a source) of the global column transistor GCT that has been turned on, respectively, the global column transistor GCT may be provided with the negative voltage VBB as a back bias voltage, and may have a gate provided with a second positive voltage VPP+a. In the state in which the global column transistor GCT and the bit line BL have been connected to a first terminal (e.g., a drain) and a second terminal (e.g., a source) of the local column transistor LCT that has been turned on, respectively, the local column transistor LCT may be provided with the negative voltage VBB as a back bias voltage, and may have a gate provided with the second positive voltage VPP+a.

The global row transistor GRT and the local row transistor LRT may be constructed to electrically connect or separate the second node node_B and a second line (e.g., a word line) WL. When the global row transistor GRT and the local row transistor LRT are turned on, the second node node_B and the word line WL may be electrically connected. At this time, a voltage that is provided to the second node node_B, that is, one of the positive voltage Positive and the negative voltage Negative, may be provided to the word line WL by the global row transistor GRT and the local row transistor LRT that have been turned on.

For example, referring to FIG. 2, when the second voltage provision transistor VT2 is turned on and the positive voltage Positive is provided to the second node node_B, the global row transistor GRT and the local row transistor LRT that have been turned on may transfer the positive voltage Positive to the word line WL. Referring to FIG. 1, when the fourth voltage provision transistor VT4 is turned on and the negative voltage Negative is provided to the second node node_B, the global row transistor GRT and the local row transistor LRT that have been turned on may transfer the negative voltage Negative to the word line WL.

At this time, as illustrated in FIGS. 1 and 2, in the state in which the word line WL and the global row transistor GRT have been connected to a first terminal (e.g., a drain) and a second terminal (e.g., a source) of the local row transistor LRT that has been turned on, respectively, the local row transistor LRT may be provided with the negative voltage VBB as a back bias voltage, and may have a control terminal (e.g., a gate) provided with the second positive voltage VPP+a. In the state in which the local row transistor LRT and the second node node_B have been connected to a first terminal (e.g., a drain) and a second terminal (e.g., a source) of the global row transistor GRT that has been turned on, respectively, the global row transistor GRT may be provided with the negative voltage VBB as a back bias voltage, and may have a control terminal (e.g., a gate) provided with the second positive voltage VPP+a.

The memory cell MC may be electrically connected to the bit line BL and the word line WL. In this case, as illustrated in FIG. 1, the direction of a current that flows from the bit line BL to the word line WL through the memory cell MC may be called the forward current \textcircled{1}. Furthermore, as illustrated in FIG. 2, the direction of a current that flows from the word line WL to the bit line BL through the memory cell MC may be called the backward current \textcircled{2}.

Among the second positive voltage VPP+a, the first positive voltage VPP, the ground voltage VSS, and the negative voltage VBB, the second positive voltage VPP+a may have the highest voltage level, and the negative voltage VBB may have the lowest voltage level. Furthermore, the first positive voltage VPP may have a voltage level between the voltage levels of the ground voltage VSS and the second positive voltage VPP+a. The negative voltage VBB may have a lower voltage level than the ground voltage VSS.

The semiconductor device according to an embodiment of the present disclosure may include the plurality of voltage provision transistors VT1 to VT4 so that voltages having different polarities are provided to the first and second nodes node_A and node_B, respectively. Furthermore, the semiconductor device may include at least one of a plurality of global first transistors (e.g., the global column transistors) GCT and at least one of a plurality of local first transistors (e.g., the local column transistors) LCT that electrically connect the bit line BL and the first node node_A. Furthermore, the semiconductor device may include at least one of a plurality of global second transistors (e.g., the global row transistors) GRT and at least one of a plurality of local second transistors (e.g., the local row transistors) LRT that electrically connect the word line WL and the second node node_B.

The semiconductor device according to an embodiment of the present disclosure may include the plurality of voltage provision transistors VT1 to VT4, at least one of the global column transistors GCT, at least one of the local column transistors LCT, at least one of the global row transistors GRT, and at least one of the local row transistors LRT, and may perform a write operation on the memory cell MC by providing the forward current 1, or the backward current 2 to the memory cell MC after the start of a write operation.

The semiconductor device constructed as described above according to an embodiment of the present disclosure can improve an area margin because the global column transistor GCT, the local column transistor LCT, the global row transistor GRT, and the local row transistor LCT are each implemented as an N type transistor having a smaller size than a P type transistor. Specifically, the semiconductor device according to an embodiment of the present disclosure may include the transistors GCT, LCT, LRT, and GRT that are N-type transistors, thereby reducing a circuit area and improving an area margin compared to when the transistors GCT, LCT, LRT, and GRT are implemented as combinations of N-type and P-type transistors (e.g., two N-type transistors and two P-type transistors). Furthermore, the N type transistors may be turned on by providing the second positive voltage VPP+a to each of the gates of the N type transistors, that is, the gates of the global column transistor GCT, the local column transistor LCT, the global row transistor GRT, and the local row transistor LRT. Accordingly, the semiconductor device constructed as described above according to an embodiment of the present disclosure can reduce the output levels of the N type transistors, that is, voltage drops, because turn-on resistance of each of the N type transistors can be reduced compared to when the N type transistors are turned on by providing the first positive voltage VPP.

However, as illustrated in FIGS. 1 and 2, when the global column transistor GCT, the local column transistor LCT, the global row transistor GRT, and the local row transistor LRT are turned on, the second positive voltage VPP+a having the highest voltage level may be provided to the gate of each of the global column transistor GCT, the local column transistor LCT, the global row transistor GRT, and the local row transistor LRT, and the negative voltage VBB having the lowest voltage level may be provided to each of the global column transistor GCT, the local column transistor LCT, the global row transistor GRT, and the local row transistor LRT as a back bias voltage. Accordingly, each of the global column transistor GCT, the local column transistor LCT, the global row transistor GRT, and the local row transistor LRT may be degraded because each transistor is subjected to stress by a difference between the voltage levels of the second positive voltage VPP+a that is provided to each gate and the negative voltage VBB that is provided as a back bias voltage.

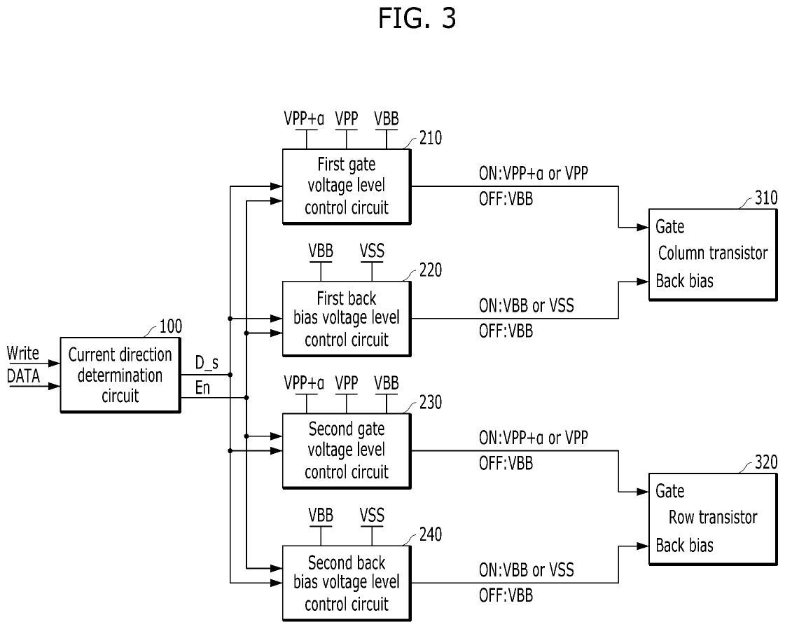

According to another embodiment of the present disclosure, a semiconductor device may provide the forward current \textcircled{1} or the backward current \textcircled{2} to the memory cell MC after the start of a write operation, and also reduce stress that is applied to the global column transistor GCT, the local column transistor LCT, the global row transistor GRT, and the local row transistor LRT when being turned on. Such an embodiment will be described below in more detail with reference to FIG. 3.

FIG. 3 is a diagram for conceptually describing a semiconductor device according to another embodiment of the present disclosure.

Referring to FIG. 3, the semiconductor device according to an embodiment of the present disclosure may include a current direction determination circuit 100, a first gate voltage level control circuit 210, a first back bias voltage level control circuit 220, a second gate voltage level control circuit 230, a second back bias voltage level control circuit 240, at least one of first transistors (e.g., column transistors) 310, and at least one of second transistors (e.g., row transistors) 320.

The current direction determination circuit 100 may generate an operation signal En and a current direction determination signal D_s based on a write command Write and data DATA. For example, when receiving the write command Write and the data DATA, the current direction determination circuit 100 may generate the operating signal En having a first value (e.g., by enabling the operation signal En), and may generate the current direction determination signal D_s based on the level of the received data DATA. In this case, when receiving the data DATA having a first level at which the forward current 1, needs to be provided to the memory cell MC, the current direction determination circuit 100 may generate the current detection determination signal D_s having a first value (e.g., by enabling the current direction determination signal D_s). When receiving the data DATA having a second level at which the backward current 2, needs to be provided to the memory cell MC, the current direction determination circuit 100 may generate the current detection determination signal D_s having a second value (e.g., by disabling the current direction determination signal D_s). When not receiving the write command Write, the current direction determination circuit 100 may generate the operation signal En having a second value (e.g., by disabling the operation signal En).

The first gate voltage level control circuit 210 may selectively provide one of the second positive voltage VPP+a, the first positive voltage VPP, and the negative voltage VBB to a gate of at least one of the column transistors 310 based on the operation signal En and the current direction determination signal D_s. For example, when the operation signal En is enabled and the current direction determination signal D_s is enabled, the first gate voltage level control circuit 210 may provide the second positive voltage VPP+a to the gate of at least one of the column transistors 310. Furthermore, when the operation signal En is enabled and the current direction determination signal D_s is disabled, the first gate voltage level control circuit 210 may provide the first positive voltage VPP to the gate of at least one of the column transistors 310. When the operation signal En is disabled, the first gate voltage level control circuit 210 may provide the negative voltage VBB to the gate of at least one of the column transistors 310.

The first back bias voltage level control circuit 220 may provide one of the negative voltage VBB and the ground voltage VSS as a back bias voltage of at least one of the column transistors 310 based on the operation signal En and the current direction determination signal D_s. For example, when the operation signal En is enabled and the current direction determination signal D_s is enabled, the first back bias voltage level control circuit 220 may provide the ground voltage VSS as the back bias voltage of at least one of the column transistors 310. Furthermore, when the operation signal En is enabled and the current direction determination signal D_s is disabled, the first back bias voltage level control circuit 220 may provide the negative voltage VBB as the back bias voltage of at least one of the column transistors 310. When the operation signal En is disabled, the first back bias voltage level control circuit 220 may provide the negative voltage VBB as the back bias voltage of at least one of the column transistors 310.

The second gate voltage level control circuit 230 may selectively provide one of the second positive voltage VPP+a, the first positive voltage VPP, and the negative voltage VBB to the gate of at least one of the row transistors 320 based on the operation signal En and the current direction determination signal D_s. For example, when the operation signal En is enabled and the current direction determination signal D_s is enabled, the second gate voltage level control circuit 230 may provide the first positive voltage VPP to the gate of at least one of the row transistors 320. Furthermore, when the operation signal En is enabled and the current direction determination signal D_s is disabled, the second gate voltage level control circuit 230 may provide the second positive voltage VPP+a to the gate of at least one of the row transistors 320. When the operation signal En is disabled, the second gate voltage level control circuit 230 may provide the negative voltage VBB to the gate of at least one of the row transistors 320.

The second back bias voltage level control circuit 240 may provide one of the negative voltage VBB and the ground voltage VSS as a back bias voltage of at least one of the row transistors 320 based on the operation signal En and the current direction determination signal D_s. For example, when the operation signal En is enabled and the current direction determination signal D_s is enabled, the second back bias voltage level control circuit 240 may provide the negative voltage VBB as the back bias voltage of at least one of the row transistors 320. Furthermore, when the operation signal En is enabled and the current direction determination signal D_s is disabled, the second back bias voltage level control circuit 240 may provide the ground voltage VSS as the back bias voltage of at least one of the row transistors 320. When the operation signal En is disabled, the second back bias voltage level control circuit 240 may provide the negative voltage VBB as the back bias voltage of at least one of the row transistors 320.

At least one of the column transistors 310 may be turned on when the second positive voltage VPP+a or the first positive voltage VPP is provided to the gate of the column transistor 310. In this case, when the at least one of the column transistors 310 is turned on because the second positive voltage VPP+a is provided to the gate of the column transistor 310, the column transistor 310 may be provided with the ground voltage VSS as a back bias voltage. Furthermore, when the at least one of the column transistors 310 is turned on because the first positive voltage VPP is provided to the gate of the column transistor 310, the column transistor 310 may be provided with the negative voltage VBB as a back bias voltage. When the at least one of the column transistors 310 is turned off because the negative voltage VBB is provided to the gate of the column transistor 310, the column transistor 310 may be provided with the negative voltage VBB as a back bias voltage.

At least one of the row transistors 320 may be turned on when the second positive voltage VPP+a or the first positive voltage VPP is provided to the gate of the row transistor 320. In this case, when the at least one of the row transistors 320 is turned on because the second positive voltage VPP+a is provided to the gate of the row transistor 320, the row transistor 320 may be provided with the ground voltage VSS as a back bias voltage. Furthermore, when the at least one of the row transistors 320 is turned on because the first positive voltage VPP is provided to the gate of the row transistor 320, the row transistor 320 may be provided with the negative voltage VBB as a back bias voltage. When the at least one of the row transistors 320 is turned off because the negative voltage VBB is provided to the gate of the row transistor 320, the row transistor 320 may be provided with the negative voltage VBB as a back bias voltage.

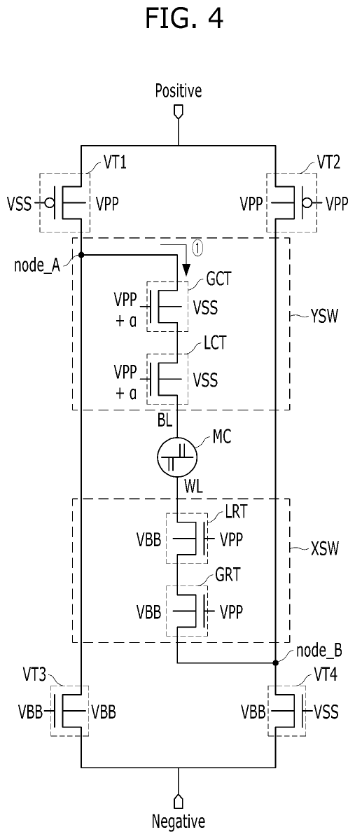

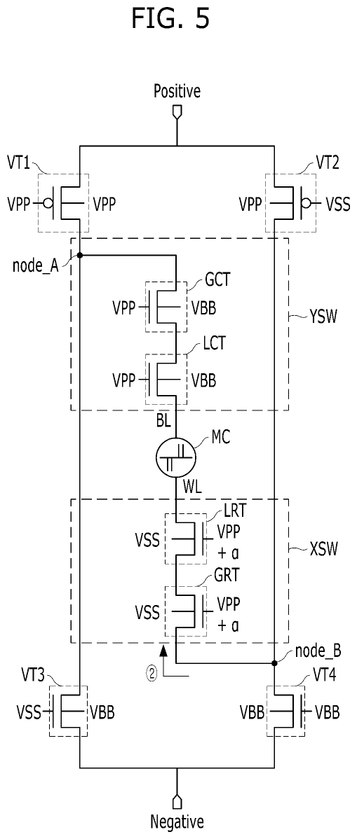

At least one of the column transistors 310 may include a global column transistor GCT and a local column transistor LCT illustrated in FIGS. 4 and 5. At least one of the row transistors 320 may also include a global row transistor GRT and a local row transistor LRT illustrated in FIGS. 4 and 5.

FIGS. 4 and 5 are diagrams for describing a structure and operation of a semiconductor device according to another embodiment of the present disclosure. FIGS. 4 and 5 are also diagrams for describing a configuration and a write operation of the semiconductor device according to another embodiment of the present disclosure. FIG. 4 is a diagram for describing a write operation of providing a forward current 1; to a memory cell MC. FIG. 5 is a diagram for describing a write operation of providing a backward current \textcircled{2} to the memory cell MC. At this time, the state of the memory cell MC may be switched between different resistance states depending on the direction of a current that is provided to the memory cell MC. That is, different data may be written into the memory cell MC depending on the direction of a current that is provided to the memory cell MC.

Referring to FIGS. 4 and 5, the semiconductor device according to another embodiment of the present disclosure may include a first voltage provision transistor VT1, a second voltage provision transistor VT2, a third voltage provision transistor VT3, a fourth voltage provision transistor VT4, a global first transistor (e.g., a global column transistor) GCT, a local first transistor (e.g., a local column transistor) LCT, a global second transistor (e.g., a global row transistor) GRT, a local second transistor (e.g., a local row transistor) LRT, and the memory cell MC. The first to fourth voltage provision transistors VT1, VT2, VT3, and VT4 may be constructed to selectively provide one of a positive voltage Positive and a negative voltage Negative to each of a first node node_A and a second node node_B. In this case, the first to fourth voltage provision transistors VT1, VT2, VT3, and VT4 may be controlled to provide the negative voltage Negative to the second node node_B when the positive voltage Positive is provided to the first node node_A. Furthermore, the first to fourth voltage provision transistors VT1, VT2, VT3, and VT4 may be controlled to provide the positive voltage Positive to the second node node_B when the negative voltage Negative is provided to the first node node_A.

For example, as illustrated in FIG. 4, when the forward current \textcircled{1} is provided to the memory cell MC, the first and fourth voltage provision transistors VT1 and VT4 may be turned on. The positive voltage Positive may be provided to the first node node_A by the first voltage provision transistor VT1 that has been turned on. The negative voltage Negative may be provided to the second node node_B by the fourth voltage provision transistor VT4 that has been turned on. As illustrated in FIG. 5, when the backward current \textcircled{2} is provided to the memory cell MC, the second and third voltage provision transistors VT2 and VT3 may be turned on. The negative voltage Negative may be provided to the first node node_A by the third voltage provision transistor VT3 that has been turned on. The positive voltage Positive may be provided to the second node node_B by the second voltage provision transistor VT2 that has been turned on.

A turn-on condition and a turn-off condition for each of the first to fourth voltage provision transistors VT1, VT2, VT3, and VT4 may be similar to those as described above with reference to FIGS. 1 and 2, and thus may be omitted for the interest of brevity.

The global column transistor GCT and the local column transistor LCT may be constructed to electrically connect or separate the first node node_A and a first line (e.g., a bit line) BL. When the global column transistor GCT and the local column transistor LCT are turned on, the global column transistor GCT and the local column transistor LCT may electrically connect the first node node_A and the bit line BL. In this case, the global column transistor GCT and the local column transistor LCT that have been turned on may provide a voltage that is provided to the first node node_A, that is, one of the positive voltage Positive and the negative voltage Negative, to the bit line BL.

For example, referring to FIG. 4, when the first voltage provision transistor VT1 is turned on and the positive voltage Positive is provided to the first node node_A, the positive voltage Positive may be transferred to the bit line BL by the global column transistor GCT and the local column transistor LCT that have been turned on. Referring to FIG. 5, when the third voltage provision transistor VT3 is turned on and the negative voltage Negative is provided to the first node node_A, the negative voltage Negative may be transferred to the bit line BL by the global column transistor GCT and the local column transistor LCT that have been turned on.

At this time, as illustrated in FIG. 4, when the forward current \textcircled{1} is provided to the memory cell MC, in the state in which the first node node_A and the local column transistor LCT have been connected to a first terminal (e.g., a drain) and a second terminal (e.g., a source) of the global column transistor GCT that has been turned on, respectively, the global column transistor GCT may be provided with a ground voltage VSS as a back bias voltage, and a second positive voltage VPP+a may be provided to a gate of the global column transistor GCT. In the state in which the global column transistor GCT and the bit line BL have been connected to a first terminal (e.g., a drain) and a second terminal (e.g., a source) of the local column transistor LCT that has been turned on, respectively, the local column transistor LCT may be provided with the ground voltage VSS as a back bias voltage, and the second positive voltage VPP+a may be provided to a control terminal (e.g., a gate) of the local column transistor LCT.

Furthermore, as illustrated in FIG. 5, when the backward current \textcircled{2} is provided to the memory cell MC, in the state in which the first node node_A and the local column transistor LCT have been connected to the drain and source of the global column transistor GCT that has been turned on, respectively, the global column transistor GCT may be provided with the negative voltage VBB as a back bias voltage, and a first positive voltage VPP may be provided to the gate of the global column transistor GCT. In the state in which the global column transistor GCT and the bit line BL have been connected to the drain and source of the local column transistor LCT that has been turned on, respectively, the local column transistor LCT may be provided with the negative voltage VBB as a back bias voltage, and the first positive voltage VPP may be provided to the gate of the local column transistor LCT.

The global row transistor GRT and the local row transistor LRT may be constructed to electrically connect or separate the second node node_B and a second line (e.g., a word line) WL. When the global row transistor GRT and the local row transistor LRT are turned on, the global row transistor GRT and the local row transistor LRT may electrically connect the second node node_B and the word line WL. In this case, the global row transistor GRT and the local row transistor LRT that have been turned on may provide a voltage that is provided to the second node node_B, that is, one of the positive voltage Positive and the negative voltage Negative, to the word line WL.

For example, referring to FIG. 5, when the second voltage provision transistor VT2 is turned on and the positive voltage Positive is provided to the second node node_B, the global row transistor GRT and the local row transistor LRT that have been turned on may transfer the positive voltage Positive to the word line WL. Referring to FIG. 4, when the fourth voltage provision transistor VT4 is turned on and the negative voltage Negative is provided to the second node node_B, the global row transistor GRT and the local row transistor LRT that have been turned on may transfer the negative voltage Negative to the word line WL.

At this time, as illustrated in FIG. 4, when the forward current \textcircled{1} is provided to the memory cell MC, in the state in which the second node node_B and the local row transistor LRT have been connected to a first terminal (e.g., a drain) and a second terminal (e.g., a source) of the global row transistor GRT that has been turned on, respectively, the global row transistor GRT may be provided with the negative voltage VBB as a back bias voltage, and the first positive voltage VPP may be provided to a control terminal (e.g., a gate) of the global row transistor GRT. In the state in which the global row transistor GRT and the word line WL have been connected to a first terminal (e.g., a drain) and a second terminal (e.g., a source) of the local row transistor LRT that has been turned on, respectively, the local row transistor LRT may be provided with the negative voltage VBB as a back bias voltage, and the first positive voltage VPP may be provided to a control terminal (e.g., a gate) of the local row transistor LRT.

Furthermore, as illustrated in FIG. 5, when the backward current \textcircled{2} is provided to the memory cell MC, in the state in which the second node node_B and the local row transistor LRT have been connected to the drain and source of the global row transistor GRT that has been turned on, respectively, the global row transistor GRT may be provided with the ground voltage VSS as a back bias voltage, and the second positive voltage VPP+a may be provided to the gate of the global row transistor GRT. In the state in which the global row transistor GRT and the word line WL have been connected to the drain and source of the local row transistor LRT that has been turned on, respectively, the local row transistor LRT may be provided with the ground voltage VSS as a back bias voltage, and the second positive voltage VPP+a may be provided to the gate of the local row transistor LRT.

The memory cell MC may be electrically connected to the bit line BL and the word line WL.

Among the second positive voltage VPP+a, the first positive voltage VPP, the ground voltage VSS, and the negative voltage VBB, the second positive voltage VPP+a may have the highest voltage level, and the negative voltage VBB may have the lowest voltage level. Furthermore, the first positive voltage VPP may have a voltage level between the voltage levels of the ground voltage VSS and the second positive voltage VPP+a. The negative voltage VBB may have a lower voltage level than the ground voltage VSS.

The semiconductor device according to another embodiment of the present disclosure may include the plurality of voltage provision transistors VT1 to VT4 so that voltages having different polarities are provided to the first and second nodes node_A and node_B, respectively. Furthermore, the semiconductor device may include at least one of a plurality of first transistors. In the embodiment of FIGS. 4 and 5, the plurality of first transistors (e.g., column transistors) YSW correspond to at least one of a plurality of global first transistors (e.g., the global column transistors) GCT and at least one of a plurality of local first transistors (e.g., the local column transistors) LCT that electrically connect the bit line BL and the first node node_A. Furthermore, the semiconductor device may include at least one of a plurality of second transistors. In the embodiment of FIGS. 4 and 5, the plurality of second transistors (e.g., row transistors) XSW correspond to at least one of a plurality of global second transistors (e.g., the global row transistors) GRT and at least one of a plurality of local second transistors (e.g., the local row transistors) LRT that electrically connect the word line WL and the second node node_B. At least one of the column transistors YSW in FIGS. 4 and 5 may correspond to at least one of the column transistors 310 in FIG. 3. Furthermore, at least one of the row transistors XSW in FIGS. 4 and 5 may correspond to at least one of the row transistors 320 in FIG. 3.

The semiconductor device according to another embodiment of the present disclosure may include the plurality of voltage provision transistors VT1 to VT4, at least one of the column transistors YSW, and at least one of the row transistors XSW, and may perform a write operation on the memory cell MC by providing the forward current \textcircled{1} or the backward current \textcircled{2} to the memory cell MC after the start of a write operation.

Furthermore, the semiconductor device according to another embodiment of the present disclosure can improve an area margin because the column transistors YSW and the row transistors XSW are each implemented as an N type transistor like the semiconductor device according to the embodiment shown in FIGS. 1 and 2 of the present disclosure. Furthermore, when each of the N type transistors (i.e., each of the column transistors YSW and the row transistors XSW) is turned on by providing the second positive voltage VPP+a to the gate of each of the N type transistors, each of the N type transistors may be provided with the ground voltage VSS as a back bias voltage. Furthermore, when each of the N type transistors (i.e., each of the column transistors YSW and the row transistors XSW) is turned on by providing the first positive voltage VPP to the gate of each of the N type transistors, each of the N type transistors may be provided with the negative voltage VBB as a back bias voltage.

In the semiconductor device according to another embodiment of the present disclosure, when the forward current \textcircled{1} or the backward current \textcircled{2} is provided to the memory cell MC, that is, when the global column transistor GCT, the local column transistor LCT, the global row transistor GRT, and the local row transistor LRT are turned on, a difference between the voltage levels of a back bias voltage and the gate of each of the global column transistor GCT, the local column transistor LCT, the global row transistor GRT, and the local row transistor LRT may be relatively small, compared to a case in which the gate of each of the global column transistor GCT, the local column transistor LCT, the global row transistor GRT, and the local row transistor LRT is provided with the second positive voltage VPP+a and each of the global column transistor GCT, the local column transistor LCT, the global row transistor GRT, and the local row transistor LRT is provided with the negative voltage VBB as a back bias voltage when the global column transistor GCT, the local column transistor LCT, the global row transistor GRT, and the local row transistor LRT are turned on in the semiconductor device according to an embodiment of the present disclosure. For example, a difference (e.g., VPP+a−VSS) between a gate voltage and a back bias voltage of each of the transistors GCT, LCT, LRT, and GRT when the transistors GCT, LCT, LRT, and GRT are turned on according to the embodiment in FIGS. 4 and 5 may be smaller than that (e.g., VPP+a−VBB) according to the embodiment in FIGS. 1 and 2. Accordingly, the semiconductor device according to another embodiment (e.g., the embodiment in FIGS. 4 and 5) of the present disclosure can further improve the reliability of a transistor by reducing stress of the transistor compared to the semiconductor device according to an embodiment (e.g., the embodiment in FIGS. 1 and 2) of the present disclosure.

Although the above-described embodiments have been provided to merely describe example embodiments according to the concept of the present disclosure, various embodiments of the present disclosure are not limited thereto. Various substitutions, modifications, and changes may be possible.

What is claimed is:

1. A semiconductor device comprising:
a memory cell connected to a first line and a second line;
at least one of first transistors each configured to provide a first input voltage of a first node to the first line; and
at least one of second transistors each configured to provide a second input voltage of a second node to the second line,
wherein the first and second nodes are provided with the first and second input voltages having different polarities,
wherein the polarities of the first and second input voltages that are provided to the first and second nodes are determined based on data to be written in the memory cell, and
wherein at least one of a voltage of each of control terminals of the first and second transistors and a back bias voltage of each of the first and second transistors is adjusted in response to a change in the polarity of each of the first and second input voltages.

2. The semiconductor device of claim 1, wherein the first line is a bit line and the second line is a word line, and
wherein, when a forward current flows through the memory cell from the bit line to the word line, a first positive voltage is applied to each of the control terminals of the second transistors and a negative voltage is provided as a back bias voltage of each of the second transistors, and a second positive voltage is applied to each of the control terminals of the first transistors and a ground voltage is provided as a back bias voltage of each of the first transistors, the second positive voltage being higher than the first positive voltage.

3. The semiconductor device of claim 2, wherein, when a backward current flows through the memory cell from the word line to the bit line, the first positive voltage is applied to each of the control terminals of the first transistors and the negative voltage is provided as the back bias voltage of each of the first transistors, and the second positive voltage is applied to each of the control terminals of the second transistors and the ground voltage is provided as the back bias voltage of each of the second transistors.

4. The semiconductor device of claim 1, wherein the first line is a bit line and the second line is a word line,
wherein the first transistors include a global column transistor and a local column transistor, and the second transistors include a global row transistor and a local row transistor,
wherein the global column transistor has a first terminal connected to the first node and a second terminal connected to the local column transistor, and the local column transistor has a first terminal connected to the second terminal of the global column transistor and a second terminal connected to the bit line, and
wherein the global row transistor has a first terminal connected to the second node and a second terminal connected to the local row transistor, and the local row transistor has a first terminal connected to the second terminal of the global row transistor and a second terminal connected to the word line.

5. The semiconductor device of claim 4, wherein each of the global column transistor, the local column transistor, the global row transistor, and the local row transistor is an N-type transistor.

6. A semiconductor device comprising:
a current direction determination circuit configured to generate an operation signal and a current direction determination signal based on a write command and data;
a first gate voltage level control circuit configured to provide one of a negative voltage, a first positive voltage, and a second positive voltage to a gate of at least one of column transistors based on the operation signal and the current direction determination signal; and
a first back bias voltage level control circuit configured to provide one of the negative voltage and a ground voltage as a back bias voltage of the at least one of the column transistors based on the operation signal and the current direction determination signal.

7. The semiconductor device of claim 6, wherein when receiving the write command, the current direction determination circuit enables the operation signal, and enables or disables the current direction determination signal based on the data.

8. The semiconductor device of claim 7, wherein the first gate voltage level control circuit:
provides the second positive voltage to the gate of the at least one of the column transistors when the operation signal is enabled and the current direction determination signal is enabled;
provides the first positive voltage to the gate of the at least one of the column transistors when the operation signal is enabled and the current direction determination signal is disabled; and
provides the negative voltage to the gate of the at least one of the column transistors when the operation signal is disabled.

9. The semiconductor device of claim 7, wherein the first back bias voltage level control circuit:
provides the ground voltage as the back bias voltage of the at least one of the column transistors when the operation signal is enabled and the current direction determination signal is enabled;
provides the negative voltage as the back bias voltage of the at least one of the column transistors when the operation signal is enabled and the current direction determination signal is disabled; and
provides the negative voltage as the back bias voltage of the at least one of the column transistors when the operation signal is disabled.

10. The semiconductor device of claim 7, further comprising:
a second gate voltage level control circuit configured to provide one of the negative voltage, the first positive voltage, and the second positive voltage to a gate of at least one of row transistors based on the operation signal and the current direction determination signal; and
a second back bias voltage level control circuit configured to provide one of the negative voltage and the ground voltage as a back bias voltage of the at least one of the row transistors based on the operation signal and the current direction determination signal.

11. The semiconductor device of claim 10, wherein the second gate voltage level control circuit:
provides the first positive voltage to the gate of the at least one of the row transistors when the operation signal is enabled and the current direction determination signal is enabled;
provides the second positive voltage to the gate of the at least one of the row transistors when the operation signal is enabled and the current direction determination signal is disabled; and
provides the negative voltage to the gate of the at least one of the row transistors when the operation signal is disabled.

12. The semiconductor device of claim 10, wherein the second back bias voltage level control circuit:
provides the negative voltage as the back bias voltage of the at least one of the row transistors when the operation signal is enabled and the current direction determination signal is enabled;
provides the ground voltage as the back bias voltage of the at least one of the row transistors when the operation signal is enabled and the current direction determination signal is disabled; and
provides the negative voltage as the back bias voltage of the at least one of the row transistors when the operation signal is disabled.

13. The semiconductor device of claim 10, further comprising:
a bit line connected to the at least one of the column transistors;
a word line connected to the at least one of the row transistors; and
a memory cell connected to the bit line and the word line.

14. The semiconductor device of claim 6, wherein among the second positive voltage, the first positive voltage, the ground voltage, and the negative voltage, the second positive voltage has a highest voltage level and the negative voltage has a lowest voltage level.

15. An operating method of a semiconductor device, comprising:
providing a positive voltage to a first node;
providing a negative voltage to a second node;
connecting the first node to a bit line that is electrically connected to a first end of a memory cell by providing a second positive voltage to a gate of a column transistor; and
connecting the second node to a word line that is electrically connected to a second end of the memory cell by providing a first positive voltage to a gate of a row transistor, the first positive voltage having a lower voltage level than the second positive voltage.

16. The operating method of claim 15, wherein the connecting of the first node to the bit line comprises providing a ground voltage as a back bias voltage of the column transistor.

17. The operating method of claim 15, wherein the connecting of the second node to the word line comprises providing a negative voltage as a back bias voltage of the row transistor.

18. An operating method of a semiconductor device, comprising:
providing a negative voltage to a first node;
providing a positive voltage to a second node;
connecting the first node to a bit line that is electrically connected to a first end of a memory cell by providing a first positive voltage to a gate of a column transistor; and
connecting the second node to a word line that is electrically connected to a second end of the memory cell by providing a second positive voltage to a gate of a row transistor, the second positive voltage having a higher voltage level than the first positive voltage.

19. The operating method of claim 18, wherein the connecting of the first node to the bit line comprises providing a negative voltage as a back bias voltage of the column transistor.

20. The operating method of claim 18, wherein the connecting of the second node to the word line comprises providing a ground voltage as a back bias voltage of the row transistor.
